(19) United States
(12) Patent Application Publication
(10) Pub. No.: US 2026/0348589 A1
(43) Pub. Date: Nov. 5, 2026

(54) COOKING APPARATUS

(71) Applicant: SAMSUNG ELECTRONICS CO., LTD., Suwon-si (KR)

(72) Inventors: Jiwon JEONG, Suwon-si (KR); Seungwoo HAN, Suwon-si (KR); Hyeongjin JANG, Suwon-si (KR); Daechul NOH, Suwon-si (KR)

(73) Assignee: SAMSUNG ELECTRONICS CO., LTD., Suwon-si (KR)

(21) Appl. No.: 19/706,561

(22) Filed: Jun. 12, 2026

Related U.S. Application Data
(63) Continuation of application No. PCT/KR2026/004570, filed on Mar. 23, 2026.

(30) Foreign Application Priority Data
Mar. 31, 2025 (KR) 10-2025-0041765
Jul. 2, 2025 (KR) 10-2025-0088478

(51) Int. Cl. F24C 7/08; F24C 7/04; F24C 15/10; F24C 15/36

(52) U.S. Cl. CPC F24C 7/083; F24C 7/043; F24C 15/10; F24C 15/36

(57) ABSTRACT

A cooking apparatus includes: a first plate having one or more cooking zones and an opening formed therein, a second plate inserted into the opening and seated on the first plate, and a display disposed in a position corresponding to a position of the opening so that visual information is displayed on the display and visible through the second plate. The first plate further comprises an inner wall surface which is a boundary surrounding inside of the opening thereby forming the opening. The inner wall surface includes a first inner wall surface formed along the boundary of the opening, and inclined to support the second plate in response to the second plate being seated on the first plate; a, and a second inner wall surface bent and extending from the first inner wall surface.

### CROSS REFERENCE TO THE RELATED APPLICATION

This application is a continuation application, filed under 35 U.S.C. § 111(a), of International Application PCT/KR2026/004570 filed Mar. 23, 2026, and is based on and claims priority under 35 U.S.C. § 119 to Korean Patent Applications No. 10-2025-0041765, filed on Mar. 31, 2025, and Korean Patent Applications No. 10-2025-0088478, filed on Jul. 2, 2025, in the Korean Intellectual Property Office, the disclosures of which are incorporated by reference herein in their entireties.

### TECHNICAL FIELD

The disclosure relates to a cooking apparatus having an improved structure.

### BACKGROUND ART

A cooking apparatus refers to a device for heating and cooking food, and may provide various cooking-related functions including heating, thawing, drying, and sterilizing of an object to be cooked. The cooking apparatus may include a gas cooktop that cooks food using gas, an electric cooktop that cooks food using electricity, and the like.

A gas cooktop, also referred to as a gas range, is an apparatus that cooks food by igniting and combusting gas in a small generator through rotation of a lever, and using the generated heat for cooking.

An electric cooktop is an apparatus that cooks food by generating heat directly or indirectly using electricity and using the generated heat.

The electric cooktops may include an induction cooktops that generate heat in a cooking container by a magnetic field formed in a coil, a highlight cooktop that directly heats a heating element using electricity, a hot plate that heats a coil-shaped heating wire below a cast iron or coated heating plate, and a halogen cooktops that heat cooks a cooking container using far-infrared power from a halogen lamp.

### DISCLOSURE

### Technical Problem

One aspect of the disclosure provides a cooking apparatus in which an opening is provided in a first plate such that a display is formed in the cooking apparatus, and a second plate is seated in the opening such that visual information of the display is displayed.

One aspect of the disclosure provides a cooking apparatus in which an inclined structure is provided on an inner wall surface of the opening such that the second plate is seated in the opening of the first plate without a separate bracket.

One aspect of the disclosure provides a cooking apparatus in which an end portion that limits extension of the inclined structure is provided on the first plate to reinforce the strength of the inclined structure of the inner wall surface of the opening.

The technical objectives of the present disclosure are not limited to the above, and other objectives that are not described above will be clearly understood by those skilled in the art from the above detailed description.

### Technical Solution

A cooking apparatus according to a concept of the disclosure includes: a first plate provided with one or more cooking zones and an opening; a second plate seated in the opening; and a display on which visual information is displayed through the second plate, wherein an inner wall surface of the opening includes a first inner wall surface inclined to support the second plate, and a second inner wall surface bent and extending from the first inner wall surface.

A cooking apparatus comprise a first plate having one or more cooking zones, the first plate having an opening formed therein, a second plate inserted into the opening and seated on the first plate, a display disposed in a position corresponding to a position of the opening so that visual information is displayed on the display and visible through the second plate.

The first plate further comprises an inner wall surface which is a boundary surrounding inside of the opening thereby forming the opening, the inner wall surface includes a first inner wall surface formed along the boundary of the opening, and inclined to support the second plate in response to the second plate being seated on the first plate, and a second inner wall surface bent and extending from the first inner wall surface.

The second plate includes a side surface which includes an inclined surface parallel to the first inner wall surface, and the inclined surface is supported by the first inner wall surface in response to the second plate being seated on the first plate.

The side surface of the second plate further includes an extension surface extending from the inclined surface in a vertical direction.

The second inner wall surface is disposed between a lower surface of the first plate and the first inner wall surface.

The second inner wall surface is disposed between an upper surface of the first plate and the first inner wall surface.

The inner wall surface includes one or more straight portions arranged along the boundary of the opening in a horizontal direction, and one or more curved portions extending from the one or more the straight portions in the horizontal direction. One or more curved portions extend from an upper surface of the first plate to a lower surface of the first plate.

The one or more curved portions have a radius of curvature that decreases in a downward direction in a section in which the first inner wall surface is formed; and a radius of curvature maintained in a downward direction in a section in which the second inner wall surface is formed.

The first inner wall surface extends from the boundary of the opening toward a center of the opening.

The second inner wall surface is disposed at one end of the first inner wall surface to limit an extension range of the first inner wall surface.

The second inner wall surface extends in a substantially vertical direction.

With respect to a thickness direction of the first plate, a height of the second inner wall surface is greater than or equal to a height of the first inner wall surface.

The height of the second inner wall surface is greater than or equal to one half of a thickness of the inner wall surface.

An upper surface of the second plate is positioned below an upper surface of the first plate in response to the second plate being seated on the first plate.

A lower surface of the second plate is positioned below a lower surface of the first plate in response to the second plate being seated on the first plate.

The lower surface of the second plate is protruded downward from the lower surface of the first plate in response to the second plate being seated on the first plate.

The display is positioned on a lower surface of the second plate, and the cooking apparatus further comprises a touch film which is attached between the second plate and the display.

The second plate is formed of a material that is relatively more transparent than a material of the first plate.

The cooking apparatus further comprises an adhesive member disposed between the first inner wall surface of the first plate and a side surface of the second plate, and the second plate further comprises a side printed surface that is opaquely printed and disposed on the side surface of the second plate.

The second plate further includes a rear printed surface that is opaquely printed and disposed at an edge of a lower surface of the second plate.

A cooking apparatus according to an embodiment of the present disclosure includes a display on which visual information is displayed; a first plate provided with one or more cooking zones and an opening having a shape including a corner at a position corresponding to the display, the opening having an inclined structure on an inner wall surface thereof; a second plate inserted into the opening of the first plate and seated on the inner wall surface, wherein the opening includes a curved portion extending from an upper surface to a lower surface of the first plate such that the corner is rounded, and the curved portion is formed such that a radius of curvature at the lower surface of the first plate is smaller than a radius of curvature at the upper surface of the first plate.

### DESCRIPTION OF DRAWINGS

FIG. 1 is a view illustrating a cooking apparatus according to an embodiment of the disclosure.

FIG. 2 is an exploded view of a part of a cooking apparatus according to an embodiment of the disclosure.

FIG. 3 is a cross-sectional view taken along line A-A′ of FIG. 2 illustrating a part of a cooking apparatus according to an embodiment of the disclosure.

FIG. 4 is an exploded view of a part of a cooking apparatus according to an embodiment of the disclosure.

FIG. 5 is an exploded view of a part of a cooking apparatus according to an embodiment of the disclosure when viewed in a different direction.

FIG. 6 is an exploded view illustrating components for forming a display portion of a cooking apparatus according to an embodiment of the disclosure.

FIG. 7 illustrates a side cross-section of a part of a cooking apparatus according to an embodiment of the disclosure.

FIG. 8 illustrates region C of FIG. 7 in a cooking apparatus according to an embodiment of the disclosure.

FIG. 9 is an enlarged view of region B of FIG. 6 in a cooking apparatus according to an embodiment of the disclosure.

FIG. 10 is a top view of FIG. 9 in a cooking apparatus according to an embodiment of the disclosure.

FIG. 11 illustrates a side cross-section of a part of a cooking apparatus according to an embodiment of the disclosure.

FIG. 12 is a rear view of a second plate in a cooking apparatus according to an embodiment of the disclosure.

FIG. 13 illustrates a side cross-section of a part of a cooking apparatus according to an embodiment of the disclosure.

FIG. 14 illustrates a side cross-section of a part of a cooking apparatus according to an embodiment of the disclosure.

FIG. 15 illustrates a side cross-section of a part of a cooking apparatus according to an embodiment of the disclosure.

FIG. 16 illustrates a side cross-section of a part of a cooking apparatus according to an embodiment of the disclosure.

FIG. 17 illustrates a side cross-section of a part of a cooking apparatus according to an embodiment of the disclosure.

### MODES OF THE DISCLOSURE

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

As used herein, the term “and/or” includes any and all combinations of one or more of associated listed items.

Terms such as “1st”, “2nd”, “primary”, or “secondary” may be used simply to distinguish a component from other components, without limiting the component in other aspects (e.g., importance or order).

It will be understood that when the terms “includes,” “comprises,” “including,” and/or “comprising,” when used in this specification, specify the presence of stated features, figures, steps, operations, components, members, or combinations thereof, but do not preclude the presence or addition of one or more other features, figures, steps, operations, components, members, or combinations thereof.

It will be understood that when a certain component is referred to as being “connected to”, “coupled to”, “supported by” or “in contact with” another component, it can be directly or indirectly connected to, coupled to, supported by, or in contact with the other component. When a component is indirectly connected to, coupled to, supported by, or in contact with another component, it may be connected to, coupled to, supported by, or in contact with the other component through a third component.

It will also be understood that when a component is referred to as being “on” another component, it can be directly on the other component or intervening components may also be present.

The terms “upper side,” “lower side,” “horizontal direction,” and the like used in the following description are defined based on the drawings, and the shapes and positions of the respective components are not limited by these terms.

Among the expressions used in the following description, terms such as “upper ~” and “lower ~” may be used to distinguish components by considering relative positions between the components, and such terms may be replaced with expressions such as “first ~” and “second ~.”

Hereinafter, embodiments according to the disclosure will be described in detail with reference to the accompanying drawings.

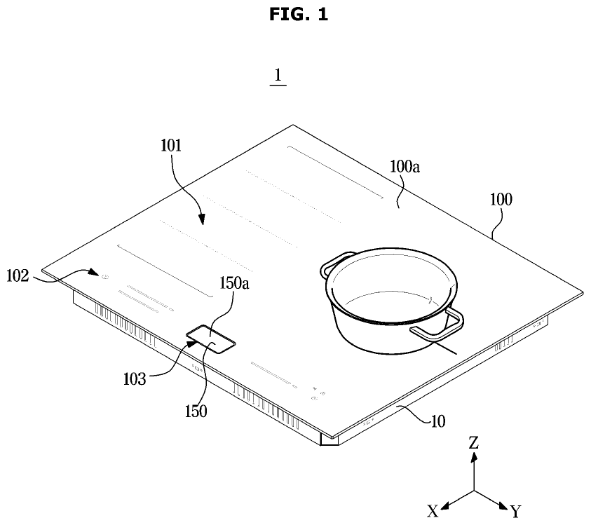

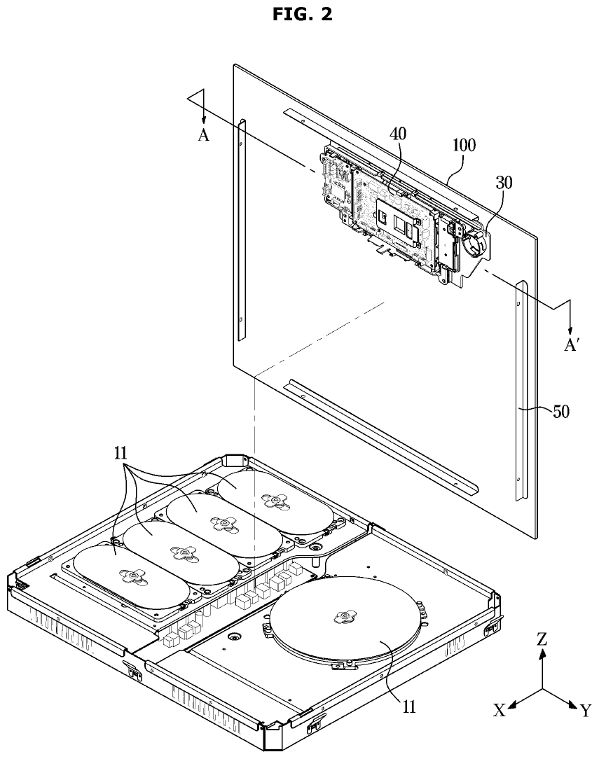

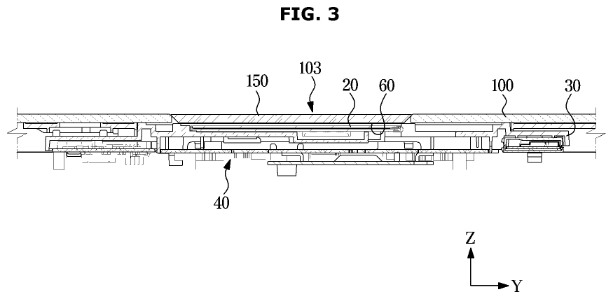

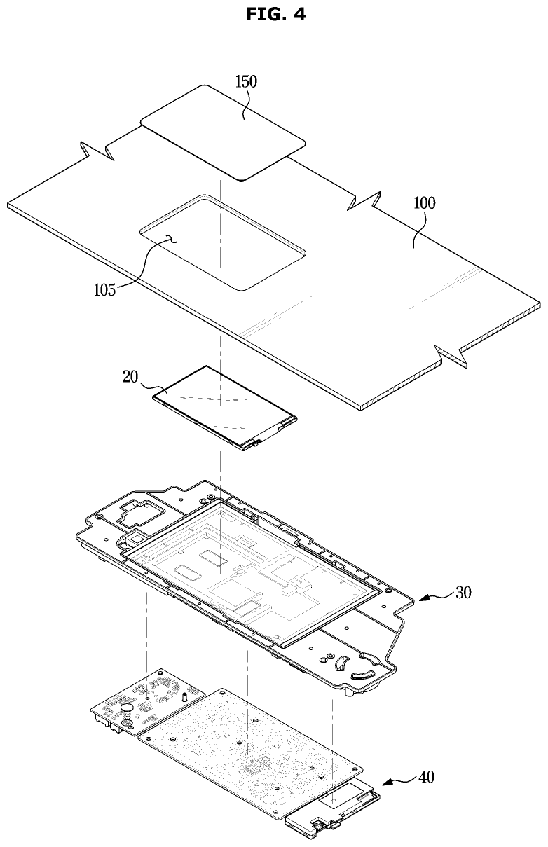

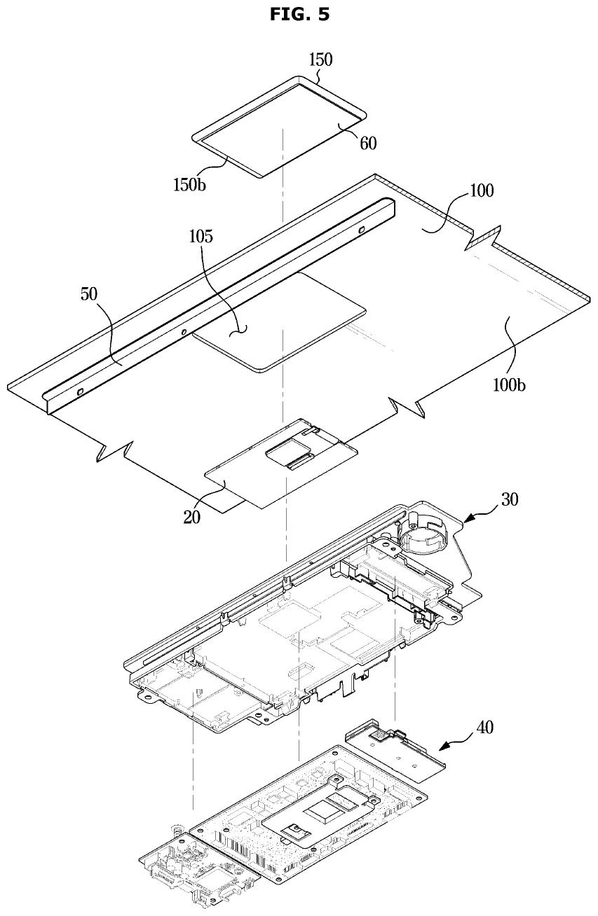

FIG. 1 is a view illustrating a cooking apparatus according to an embodiment of the disclosure. FIG. 2 is an exploded view of a part of a cooking apparatus according to an embodiment of the disclosure. FIG. 3 is a cross-sectional view taken along line A-A′ of FIG. 2 illustrating a part of a cooking apparatus according to an embodiment of the disclosure. FIG. 4 is an exploded view of a part of a cooking apparatus according to an embodiment of the disclosure. FIG. 5 is an exploded view of a part of a cooking apparatus according to an embodiment of the disclosure when viewed in a different direction.

Referring to FIGS. 1 to 5, a cooking apparatus 1 may include a main body 10 that forms an external appearance and in which various components are installed, and a top plate provided on an upper side of the main body. The top plate may include a first plate 100.

The cooking apparatus 1 may include the first plate 100 positioned on the upper side of the main body 10. The first plate 100 may have a flat plate shape on which a cooking container may be seated. For example, the first plate 100 may include ceramic glass and/or tempered glass. For example, the first plate 100 may include heat-resistant glass that is resistant to heat.

The first plate 100 may include various materials. The first plate 100 may have a property that light does not pass therethrough. The first plate 100 may include a substantially opaque material. In addition, the first plate 100 may have a characteristic of transmitting a touch signal to a circuit board 40 provided on a lower side through a touch operation.

The cooking apparatus 1 may include at least one heating source 11 for cooking food. The heating source 11 may be provided inside the main body 10 or on the first plate 100. The heating source 11 may be positioned below the first plate 100.

In an embodiment of the disclosure, the heating source 11 is illustrated as an induction heating coil of an induction cooktop, but the concept of the disclosure is not limited thereto. The heating source 11 may include various embodiments capable of heating food provided on the first plate 100. For example, the heating source 11 may include various heating sources such as an electric coil, an electric heater, a gas burners, and the like that generates heat.

The main body 10 may be provided such that the first plate 100 is supported thereon. The first plate 100 may include a frame 50 that allows the first plate 100 to be coupled to the main body 10. The frame 50 may be provided on a lower surface 100b of the first plate 100. The frame 50 may be provided on an outer periphery of the lower surface 100b of the first plate 100. The frame 50 may be fixed to the lower surface 100b of the first plate 100.

The frame 50 may be provided to be coupled to the main body 10. For example, the frame 50 may be provided to allow a fixing member to pass therethrough. The frame 50 may be coupled to the main body 10 through the fixing member. The first plate 100 may be coupled to the main body 10 through the frame 50.

The first plate 100 may include one or more cooking zones 101 in which food is cooked. The cooking zones 101 may be provided at positions corresponding to the heating sources 11. The cooking zone 101 may be formed on an upper surface 100a of the first plate 100. The number and positions of the cooking zones 101 are not limited to those illustrated.

The first plate 100 may be provided on one side thereof with a user interface 102 for receiving control commands from a user and displaying operation information of the cooking apparatus 1 to the user. However, the position of the user interface 102 is not limited to the first plate 100, and may be provided at various positions such as a front surface and/or a side surface of the main body 10.

The cooking apparatus 1 may include a display 20 and a circuit board 40. The display 20 and the circuit board 40 may be disposed below the first plate 100. The cooking apparatus 1 may include a bracket 30 on which the display 20 and the circuit board 40 are disposed. The bracket 30 may be provided such that the display 20 and the circuit board 40 are fixed thereto. The display 20 may be seated on and coupled to an upper side of the bracket 30. The circuit board 40 may be coupled to a lower side of the bracket 30.

The bracket 30 may be attached to the lower surface 100b of the first plate 100. Accordingly, the display 20 and the circuit board 40 may be provided on the lower surface 100b of the first plate 100. In the drawings, the display 20 and the circuit board 40 are illustrated as being coupled to the lower surface 100b of the first plate 100 through the bracket 30, the concept of the disclosure is not limited thereto. The display 20 and the circuit board 40 may be provided in various embodiments positioned on a lower side of the first plate 100. For example, the display 20 and the circuit board 40 may be accommodated inside the main body 10. The display 20 and the circuit board 40 may be positioned inside the main body 10 and spaced apart from the first plate 100.

The circuit board 40 may include a printed board assembly (PBA) including switch elements, integrated circuit elements, and the like for implementing the user interface 102, and a printed circuit board (PCB) on which the elements are installed.

The user interface 102 may be provided to receive control commands from a user. The user interface 102 may include an input portion. A user may control the cooking apparatus 1 by manipulating the input portion of the user interface 102.

For example, a touch portion may be provided on the printed circuit. The touch portion may be disposed to correspond to the user interface 102 of the first plate 100. The touch portion may be disposed to correspond to the input portion. The touch portion may receive touch signals from a user. For example, the touch portion may receive an input in a capacitive touch manner. However, the disclosure is not limited thereto, and the touch portion may receive an input in a resistive touch manner. A user may determine the degree to which food is heated through the user interface 102.

The first plate 100 may be provided on one side thereof with a display portion 103. For example, the display portion 103 may be included in the user interface 102.

The display portion 103 may be provided such that a user may recognize visual information displayed on the display 20. The display 20 may be disposed to correspond to the display portion 103 of the first plate 100. Operation information of the cooking apparatus 1 may be displayed on the display 20.

The display portion 103 may be provided to receive a touch input while performing a visual information display function. The display portion 103 may be provided to allow a user to input desired commands or control signals by directly touching the display portion 103. For example, the display portion 103 may be provided to detect a touch input from a user and perform a corresponding operation.

The cooking apparatus 1 may be provided such that the display portion 103 is formed on the first plate 100. The cooking apparatus 1 may include the display 20 provided on a lower side of the first plate 100. The first plate 100 may include an opening 105 formed at a position corresponding to the display 20. The cooking apparatus 1 may include a second plate 150 inserted into or fitted into the opening 105 of the first plate 100.

The display portion 103 may be formed on the first plate 100. The first plate 100 may include the opening 105 such that the display portion 103 is formed. The opening 105 may be provided at a position corresponding to the display 20. Accordingly, visual information of the display 20 may be exposed to an upper side of the first plate 100 through the opening 105.

The display portion 103 may be provided such that visual information of the display 20 is displayed through the second plate 150. The second plate 150 may be accommodated in the opening 105. Accordingly, the second plate 150 may be disposed at a position corresponding to the display 20. The second plate 150 may be positioned on an upper side of the display 20.

The second plate 150 may include various materials. The second plate 150 may have a property that light passes therethrough. The second plate 150 may include a substantially transparent material. The second plate 150 may be formed of a material that is relatively more transparent than the first plate 100. The relatively more transparent material may refer to a material having a higher light transmittance or capable of clearly transmitting visual information compared to the first plate 100. Accordingly, visual information displayed on the display 20 may be transmitted through the second plate 150 and be recognized by a user.

For example, the second plate 150 may include glass formed of a transparent material. For example, the second plate 150 may include a material having transparency and heat resistance such as acrylic. The second plate 150 may include various materials through which visual information of the display 20 may be recognized by a user.

In addition, the second plate 150 may have a characteristic of transmitting a touch signal to the circuit board 40 provided on a lower side through touch. A touch film 60 may be printed or attached to a lower surface 150b of the second plate 150. The user may input desired commands or control signals by touching an upper surface 150a of the second plate 150.

The circuit board 40 may be provided on a lower side of the first plate 100 and may receive touch signals output from the touch film 60. The circuit board 40 may be provided on the lower surface 100b of the first plate 100 and may be disposed adjacent to the touch film 60 provided on the lower surface 150b of the second plate 150. In other words, the circuit board 40 may be attached to the lower surface 100b of the first plate 100, so that the distance between the circuit board 40 and the touch film 60 may be minimized. Accordingly, the circuit board 40 may rapidly and accurately receive touch input signals.

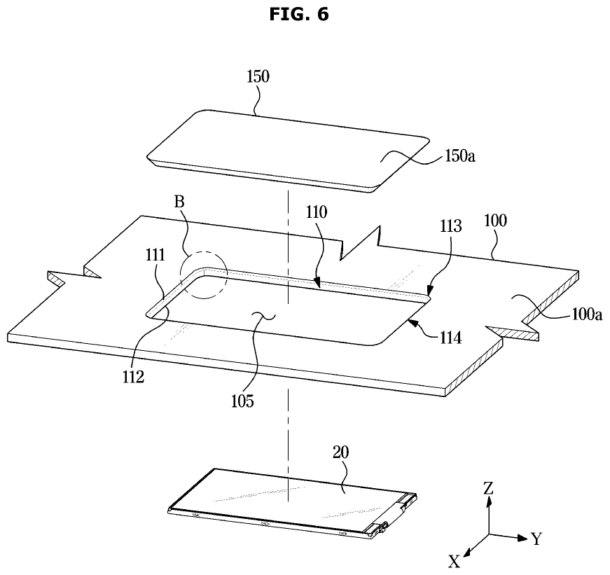

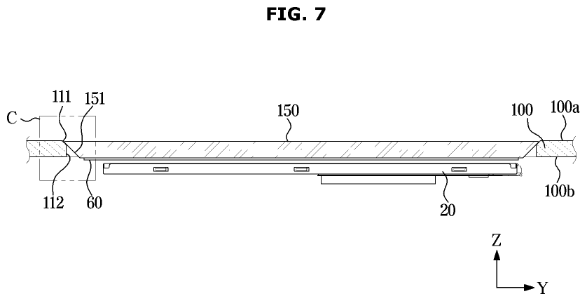

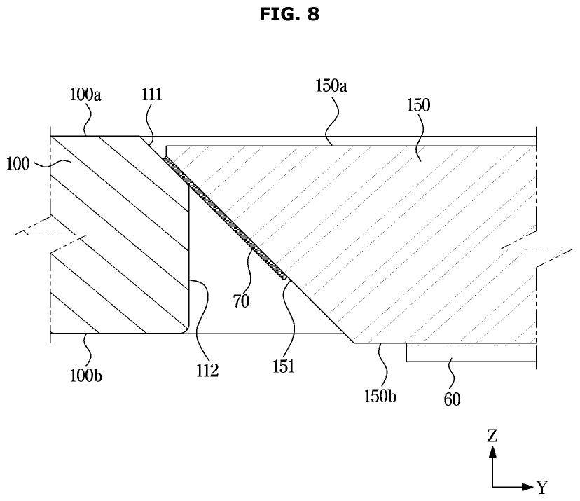

FIG. 6 is an exploded view illustrating components for forming a display portion of a cooking apparatus according to an embodiment of the disclosure. FIG. 7 illustrates a side cross-section of a part of a cooking apparatus according to an embodiment of the disclosure. FIG. 8 illustrates region C of FIG. 7 in a cooking apparatus according to an embodiment of the disclosure.

Referring to FIGS. 6 to 8, the display portion 103 may include a display 20 that displays visual information, an opening 105 formed in the first plate 100 such that the display 20 is exposed, and a second plate 150 inserted into the opening 105 to cover the display 20 from an upper side.

The cooking apparatus 1 according to an embodiment of the disclosure may be provided such that the second plate 150 is seated in the opening 105 of the first plate 100. The second plate 150 may be seated on and pressed against the first plate 100, and thus coupled to the first plate 100 without a separate support member.

Specifically, a configuration in which a separate bracket 30 or the like is fixed between the first plate 100 and the second plate 150 may not be provided. The number of components manufactured in a process of manufacturing the top plate of the cooking apparatus 1 may be reduced. Accordingly, the manufacturing cost of the top plate of the cooking apparatus 1 may be reduced. Accordingly, as the first plate 100 and the second plate 150 are coupled to each other, the number of tolerance designs required for the top plate of the cooking apparatus 1 may be reduced.

An inner wall surface 110 of the opening 105 may be provided such that the second plate 150 is seated thereon. The inner wall surface 110 may refer to a wall surrounding the inside of the opening 105.

The inner wall surface 110 may include an inclined structure. The inclined structure of the inner wall surface 110 may be provided to be inclined downward toward a center of the opening 105. The inner wall surface 110 may include the inclined structure and may be formed to extend from the circumference of the opening 105 toward the center of the opening 105. As the inner wall surface 110 is provided in a structure extending toward the center of the opening 105, the second plate 150 may be seated in the opening 105 by the inner wall surface 110.

More specifically, in order to form the inclined structure, the inner wall surface 110 of the opening 105 may include a first inner wall surface 111 having an inclined shape and a second inner wall surface 112 bent from the first inner wall surface 111. The first inner wall surface 111 and the second inner wall surface 112 may be provided to form the inner wall surface 110 of the opening 105.

The first inner wall surface 111 may be provided to be inclined downward from the boundary of the opening 105 toward the center of the opening 105. The first inner wall surface 111 may extend from the boundary of the opening 105 toward the center of the opening 105. Accordingly, the first inner wall surface 111 may be provided to support the second plate 150 inserted into the opening 105. The second plate 150 may be seated on the first inner wall surface 111. The first inner wall surface 111 may support the second plate 150 upward from below the second plate 150.

As the inner wall surface 110 of the opening 105 is provided to be inclined, the second plate 150 may be seated directly on the first plate 100. As components such as a bracket provided between the second plate 150 and the first plate 100 are eliminated, the manufacturing cost of the top plate of the cooking apparatus 1 may be reduced. In addition, as components between the first plate 100 and the second plate 150 are eliminated, the number of tolerance designs required during manufacturing of the top plate of the cooking apparatus 1 may be reduced. Accordingly, the defect rate during manufacturing of the top plate of the cooking apparatus 1 may be reduced.

In the drawing, the first inner wall surface 111 is illustrated as being inclined at an angle of approximately 45 degrees. Preferably, the first inner wall surface 111 may be provided to be inclined at an angle of 40 to 50 degrees from the lower surface 100b of the first plate 100. However, the concept of the disclosure is not limited thereto. An angle formed between the first inner wall surface 111 and the lower surface 100b of the first plate 100 may be provided within various ranges in which the first inner wall surface 111 may stably support the second plate 150 against gravity. For example, the first inner wall surface 111 may be provided to have an angle between 20 and 70 degrees with the lower surface 100b of the first plate 100.

The second inner wall surface 112 may be provided on one side of the first inner wall surface 111. The second inner wall surface 112 may be bent and extend from the first inner wall surface 111. The inner wall surface 110 may have the first inner wall surface 111 extending toward the center of the opening 105 at an inclination and may be bent at a certain point to transition to the second inner wall surface 112. The second inner wall surface 112 may extend along a thickness direction of the first plate 100. In other words, the second inner wall surface 112 may extend in a vertical direction or a direction close thereto.

By including the second inner wall surface 112, the inner wall surface 110 may be provided such that extension of the first inner wall surface 111 toward the center of the opening 105 is limited. By including the second inner wall surface 112, the inner wall surface 110 may form an end portion at one end of the first inner wall surface 111. Accordingly, the inner wall surface 110 may be provided such that the strength of the first plate 100 is reinforced. A detailed description of the features of the second inner wall surface 112 of the inner wall surface 110 will be described below in other drawings below.

The opening 105 may be provided in a shape approximately corresponding to the shape of the display 20. The opening 105 may be provided in a substantially quadrangular shape. The opening 105 may be provided in a shape in which corners are formed.

The circumference of the opening 105 may include straight portions linearly extending and curved portions connecting the straight portions with a radius of curvature, based on a cross section in a horizontal direction. Based on a cross section in a horizontal direction, the outer boundary of the opening 105 may form a closed loop. Based on a cross section in a horizontal direction, the straight portions and the curved portions may be alternately arranged along the outer boundary of the opening 105.

Accordingly, the inner wall surface 110 of the opening 105 may include the straight portions 114 including straight sections, and the curved portions 113 including curved section. The straight portions 114 may linearly extend in the horizontal direction. The curved portions 113 may extend in a curve manner in the horizontal direction.

The curved portions 113 may be provided to extend downward from the upper surface 100a of the first plate 100 to the lower surface 100b. The straight portions 114 may be provided to extend downward from the upper surface 100a of the first plate 100 to the lower surface 100b. Accordingly, the curved portions 113 may be provided on both the first inner wall surface 111 and the second inner wall surface 112. Accordingly, the straight portions 114 may be provided on both the first inner wall surface 111 and the second inner wall surface 112.

In the opening 105 provided in a substantially quadrangular shape, the curved portions 113 may be provided at the corners of the opening 105. In the opening 105 provided in a substantially quadrangular shape, the straight portions 114 may be provided in areas excluding the corners from the edges of the opening 105.

The first plate 100 of the cooking apparatus 1 according to an embodiment of the disclosure may include the curved portions 113 on the inner wall surface 110 of the opening 105 such that the corners of the opening 105 are rounded. Accordingly, when the second plate 150 is seated on the inner wall surface 110 of the opening 105, concentration of stress at the corners of the inner wall surface 110 may be prevented.

Specifically, when the second plate 150 is seated on the inner wall surface 110, the second plate 150 may apply stress to the inner wall surface 110 due to load. Alternatively, an impact due to load, such as a container falling, may be applied to the top plate of the cooking apparatus 1. Stress due to load may act more strongly at corners of the opening 105 provided in a relatively sharp shape. Accordingly, the inner wall surface 110 may be more vulnerable to damage at the corners of the opening 105.

The opening 105 may be provided in a polygonal shape. For example, the opening 105 may be provided in a substantially quadrangular shape. When sharp corners are formed at the edges of the opening 105, stress may be concentrated at the corners of the opening 105. Accordingly, in order to compensate for the vulnerability of the inner wall surface 110 at the corners of the opening 105, the curved portions 113 may be provided at the corners of the opening 105. In other words, the curved portions 113 may be formed on the inner wall surface 110 at positions corresponding to the corners of the opening 105.

As the curved portions 113 are provided at the corners of the opening 105, stress concentration that may occur when the corners of the opening 105 have a sharp shape may be alleviated. The inner wall surface 110 may have stress concentration alleviated as the curved portions 113 are formed at the corners of the opening 105. Stress acting on the inner wall surface 110 may be distributed along the curved portions 113 at the corners of the opening 105.

Meanwhile, a horizontal extension length of the straight portions 114 may be longer than a horizontal extension length of the curved portions 113. As the length of the curved portions 113 increases, stress concentration at the corners of the opening 105 may be further prevented. However, as the length of the curved portions 113 increases, the shape of the opening 105 may become closer to a circular shape from a quadrangular shape. The length of the curved portions 113 in the horizontal direction may be appropriately provided between a length for distributing stress and a length for maintaining the shape of the opening 105.

A specific structure for distributing stress on the inner wall surface 110 of the first plate 100 will be described below with reference to other drawings.

The second plate 150 may be accommodated in the opening 105 of the first plate 100.

The side surface of the second plate 150 may be provided to be inclined. The second plate 150 may include an inclined surface 151 on a side surface. The inclined surface 151 of the second plate 150 may be provided to be parallel to the first inner wall surface 111 of the opening 105. The inclined surface 151 of the second plate 150 may be provided to be inclined downward toward the center of the second plate 150.

Accordingly, when the second plate 150 is seated on the first plate 100, the side surface of the second plate 150 may be provided to be in contact with the inner wall surface 110 of the opening 105. The side surface of the second plate 150 and the inner wall surface 110 of the opening 105 may be in surface contact with each other. Accordingly, the second plate 150 may be stably supported on the first plate 100. Accordingly, stress applied to the first plate 100 by the second plate 150 may be distributed.

When the second plate 150 is inserted and seated in the opening 105 of the first plate 100, the second plate 150 may be provided to have high integrity with the first plate 100. The inclined surface 151 of the second plate 150 may be provided to have the same inclination as the first inner wall surface 111 of the opening 105. The inclined surface 151 of the second plate 150 and the first inner wall surface 111 of the opening 105 may be provided to be in surface contact with each other. Accordingly, the sense of unity between the first plate 100 and the second plate 150 may be increased. Accordingly, the aesthetics of the display portion 103 provided on the first plate 100 may be increased.

The second plate 150 inserted into the opening 105 of the first plate 100 may be automatically aligned to a seating position. The second plate 150 may be automatically aligned in a horizontal direction in the opening 105. As the inner wall surface 110 of the opening 105 is provided to be inclined, the second plate 150 may slide on the first inner wall surface 111 so as to be positioned in a correct position.

Specifically, the inclined surface 151 of the second plate 150 may be provided along the circumference of the second plate 150. The first inner wall surface 111 of the opening 105 may be provided along the circumference of the opening 105. When the second plate 150 is seated on the first plate 100, the inclined surface 151 of the second plate 150 and the first inner wall surface 111 of the opening 105 may be provided to be in surface contact with each other at all portions provided along each circumference. Accordingly, even when misalignment occurs when the second plate 150 is inserted into the opening 105, the second plate 150 may move in a direction to compensate for the misalignment inside the opening 105 to be seated on the first plate 100.

When the second plate 150 is seated on the first plate 100, the second plate 150 may be completely inserted into the opening 105. For example, a height at which the second plate 150 is positioned may be lower than a height at which the first plate 100 is positioned.

When the second plate 150 is seated on the first plate 100, the upper surface 150a of the second plate 150 may be provided to be positioned lower than the upper surface 100a of the first plate 100. The upper surface 150a of the second plate 150 may be provided to be recessed downward from the upper surface 100a of the first plate 100. The upper surface 150a of the second plate 150 may not protrude upward from the upper surface 100a of the first plate 100.

Accordingly, even when manufacturing tolerances occur during manufacturing of the top plate of the cooking apparatus 1 according to an embodiment of the disclosure, the upper surface 150a of the second plate 150 may be prevented from protruding above the upper surface 100a of the first plate 100. Accordingly, a defect rate of the top plate manufacturing process of the cooking apparatus 1 may be reduced.

Accordingly, the cooking apparatus 1 according to an embodiment of the disclosure may prevent scratching of cooking containers by the second plate 150. Even when a user moves a cooking container on the upper surface 100a of the first plate 100, the second plate 150 and the cooking container may be prevented from interfering with each other. Accordingly, the second plate 150 and/or the cooking container may be prevented from being damaged.

When the second plate 150 is seated on the first plate 100, the lower surface 150b of the second plate 150 may be provided to be positioned lower than the lower surface 100b of the first plate 100. The lower surface 150b of the second plate 150 may be provided to protrude downward from the lower surface 100b of the first plate 100. The lower surface 150b of the second plate 150 may be provided not to be recessed upward from the lower surface 100b of the first plate 100.

Accordingly, the second plate 150 according to an embodiment of the disclosure may be provided such that the touch film 60 is attached to the lower surface 150b. For example, after the touch film 60 is attached to the lower surface 150b of the second plate 150, the touch film 60 may be pressed against the lower surface 150b of the second plate 150 through a tool such as a roller. A process of attaching the touch film 60 to the lower surface 150b of the second plate 150 may be performed after the second plate 150 and the first plate 100 are coupled to each other. When the second plate 150 is coupled to the first plate 100, the lower surface 150b of the second plate 150 protrudes from the lower surface 100b of the first plate 100, and thus even after the second plate 150 is coupled to the first plate 100, the touch film 60 attached to the lower surface 150b of the second plate 150 may be pressed against the lower surface 150b of the second plate 150 through a tool such as a roller. However, a manufacturing method of the disclosure is not limited thereto.

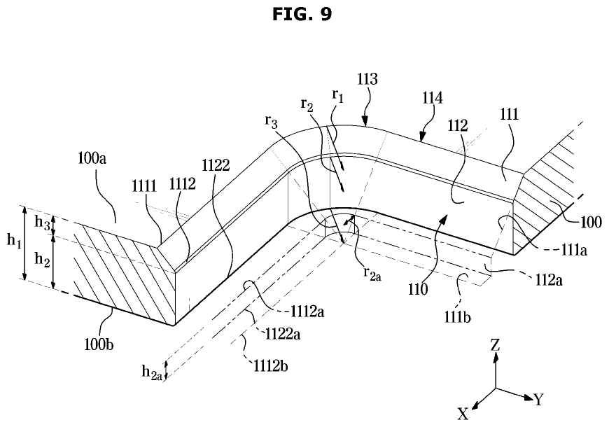

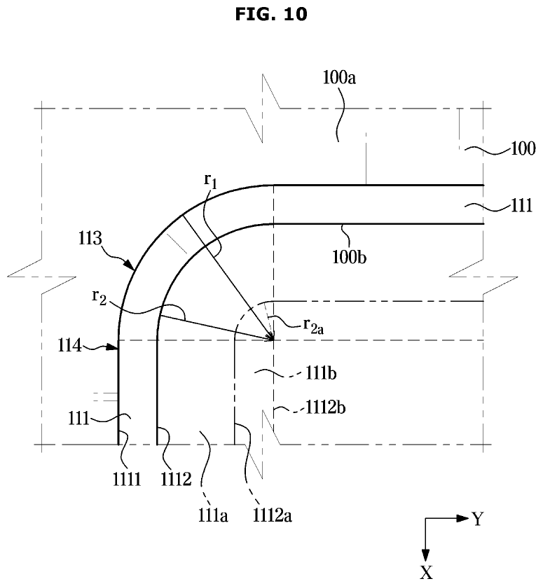

FIG. 9 is an enlarged view of region B of FIG. 6 in a cooking apparatus according to an embodiment of the disclosure. FIG. 10 is a top view of FIG. 9 in a cooking apparatus according to an embodiment of the disclosure.

Referring to FIGS. 9 and 10, the first plate 100 may include a second inner wall surface 112 to increase the strength of the inner wall surface 110 and distribute stress acting on the inner wall surface 110.

The inner wall surface 110 may include an inclined structure. The inner wall surface 110 may include a first inner wall surface 111 having an inclination. The inclination of the first inner wall surface 111 may be provided to be directed downward toward the center of the opening 105. Accordingly, the thickness of the first plate 100 at the inner wall surface 110 may become thinner as the downward inclined first inner wall surface 111 extends toward the center of the opening 105. In other words, the thickness of the first plate 100 at the inner wall surface 110 may become thinner as the length of the first inner wall surface 111 increases.

According to an embodiment of the disclosure, an end portion may be formed at the end of the inclined structure of the inner wall surface 110 of the first plate 100. The end portion may be formed at the end of the first inner wall surface 111 of the first plate 100. The second inner wall surface 112 may be provided at the end of the first inner wall surface 111.

The second inner wall surface 112 may be provided such that the range in which the first inner wall surface 111 extends is limited. For example, the second inner wall surface 112 may be provided to be bent from the first inner wall surface 111 and extend in substantially in a vertical direction. The inclined structure of the inner wall surface 110 of the first plate 100 may be provided to be stepped with respect to the lower surface 100b of the first plate 100.

As the first plate 100 includes the second inner wall surface 112, the first plate 100 may be provided such that a range in which the first inner wall surface 111 extends downward while being inclined toward the center of the opening 105 is limited. Accordingly, reduction in the thickness of the first plate 100 at the inner wall surface 110 may be limited.

Accordingly, the first plate 100 may ensure a structural thickness at the inner wall surface 110. The strength of the first plate 100 at the inner wall surface 110 may be increased. Resistance of the inner wall surface 110 of the first plate 100 to damage may be increased.

In addition, the second inner wall surface 112 may be provided to prevent stress from being more concentrated as the inner wall surface 110 becomes sharper at the corners of the opening 105.

Specifically, the curved portion 113 may be provided at the corner of the opening 105 to prevent stress from being concentrated on the inner wall surface 110. The curved portion 113 may be provided such that a predetermined radius of curvature is formed at the corner of the opening 105. The curved portion 113 may have a shape with a radius of curvature. As the radius of curvature of the curved portion 113 increases, the corner of the opening 105 may become more gradual. Accordingly, stress acting on the inner wall surface 110 at the corner of the opening 105 may be more distributed as the radius of curvature of the curved portion 113 increases.

The curved portion 113 may be provided on the inner wall surface 110. The curved portion 113 may be provided to extend from the upper surface 100a of the first plate 100 to the lower surface 100b of the first plate 100. In other words, the curved portion 113 may be provided on both the first inner wall surface 111 and the second inner wall surface 112.

As the first inner wall surface 111 is provided to be inclined downward toward the center of the opening 105, a radius of curvature of the curved portion 113 provided on the first inner wall surface 111 may be provided to decrease toward the center of the opening 105. As the first inner wall surface 111 is provided to be inclined downward toward the center of the opening 105, a radius of curvature of the curved portion 113 provided on the first inner wall surface 111 may be provided to decrease in a downward direction.

That is, the curved portion 113 may be formed such that a radius of curvature at the lower surface 100b of the first plate 100 is smaller than a radius of curvature at the upper surface 100a of the first plate 100. However, the radius of curvature of the curved portion 113 at the lower surface 100b of the first plate 100 may be provided to have a predetermined length.

That is, the corners of the opening 105 at the lower surface 100b of the first plate 100 may be rounded. The corners of the opening 105 at the lower surface 100b of the first plate 100 may be prevented from becoming pointed. Fracture due to stress concentration at the lower portion of the corners of the opening 105 may be prevented.

Specifically, when the curved portions 113 extend downward from the upper surface 100a of the first plate 100 toward the lower surface 100b, the radius of curvature of the curved portions 113 may be provided to decrease in a downward direction in a section in which the first inner wall surface 111 is formed. When the curved portions 113 extend downward from the upper surface 100a of the first plate 100 toward the lower surface 100b, the radius of curvature of the curved portions 113 may be provided to be maintained in a downward direction in a section in which the second inner wall surface 112 is formed.

Accordingly, by including the second inner wall surface 112, the inner wall surface 110 may prevent the radius of curvature of the curved portions 113 provided at the corners of the opening 105 from decreasing. By including the second inner wall surface 112, the inner wall surface 110 may prevent the corners of the opening 105 at which the curved portions 113 are formed from becoming more pointed in a downward direction. By including the second inner wall surface 112, the inner wall surface 110 may prevent stress from being concentrated at the corners of the opening 105. By including the second inner wall surface 112, the inner wall surface 110 may prevent the inner wall surface 110 from becoming vulnerable to fracture at the corners of the opening 105.

To this end, the second inner wall surface 112 may be provided to have a predetermined length. For example, a height h2 of the second inner wall surface 112 in the inner wall surface 110 may be provided to be greater than or equal to one half of a thickness h1 of the first plate 100. For example, the height h2 of the second inner wall surface 112 in the inner wall surface 110 may be provided to be greater than or equal to a height h3 of the first inner wall surface 111 in the inner wall surface 110.

However, the concept of the disclosure is not limited thereto. For example, when the first plate 100 has a large thickness, even when the height h2 of the second inner wall surface 112 in the inner wall surface 110 is less than one half of the thickness h1 of the first plate 100, the inner wall surface 110 of the opening 105 may not be vulnerable to fracture.

Hereinafter, the structure of the inner wall surface 110 will be described in detail through comparison with a case in which the first inner wall surface 111 of the inner wall surface 110 extends along the inclination and the second inner wall surface 112 is reduced or eliminated.

In one embodiment, the first inner wall surface 111 may extend between a first edge 1111 and a second edge 1112. The second inner wall surface 112 may extend between the second edge 1112 and a third edge 1122.

In one embodiment, the height h2 of the second inner wall surface 112 in the inner wall surface 110 may be provided to be greater than or equal to the height h3 of the first inner wall surface 111.

The first edge 1111 may refer to a boundary of the opening 105 at the upper surface 100a of the first plate 100. The second edge 1112 may refer to a boundary of the opening 105 at a portion in which the first inner wall surface 111 and the second inner wall surface 112 are connected to each other. The third edge 1122 may refer to a boundary of the opening 105 at the lower surface 100b of the first plate 100.

The inner wall surface 110 may include the second inner wall surface 112 extending from the second edge 1112. Accordingly, the first inner wall surface 111 extending from the first edge 1111 may extend up to the second edge 1112. An extension range of the first inner wall surface 111 may be limited a range from the first edge 1111 to the second edge 1112.

Accordingly, reduction in thickness of the inner wall surface 110 of the first plate 100 may be limited. The minimum value of the thickness of the inner wall surface 110 may be a thickness of the inner wall surface 110 at the position of the second edge 1112. The minimum value of the thickness of the first plate 100 at the inner wall surface 110 may be the height h2 of the second inner wall surface 112 in the inner wall surface 110. In other words, in one embodiment, the minimum value of the thickness of the first plate 100 at the inner wall surface 110 may be provided to be greater than or equal to one half of the thickness h1 of the first plate 100.

Accordingly, reduction in the radius of curvature of the curved portion 113 at the corner of the opening 105 may be limited. In the first inner wall surface 111, the curved portion 113 may extend from the first edge 1111 to the second edge 1112. As the curved portion 113 extends from the first edge 1111 to the second edge 1112, the radius of curvature of the curved portion 113 may decrease. A radius of curvature r2 of the curved portion 113 at the second edge 1112 may be smaller than a radius of curvature r1 of the curved portions 113 at the first edge 1111.

In the second inner wall surface 112, the curved portion 113 may extend from the second edge 1112 to the third edge 1122. Even as the curved portion 113 extends from the second edge 1112 to the third edge 1122, the radius of curvature of the curved portions 113 may be maintained. The radius of curvature r2 of the curved portion 113 at the second edge 1112 may be substantially the same as a radius of curvature r3 of the curved portions 113 at the third edge 1122.

The radius of curvature r1 at the first edge 1111 may refer to a radius of curvature of the corner of the opening 105 at the upper surface 100a of the first plate 100. The radii of curvature r2 and r3 at the second edge 1112 and the third edge 1122 may refer to a radius of curvature of the corner of the opening 105 at the lower surface 100b of the first plate 100. According to one embodiment, the radius of curvature r3 of the opening 105 at the lower surface 100b of the first plate 100 may be provided to be greater than or equal to one half of the radius of curvature r1 of the opening 105 at the upper surface 100a of the first plate 100.

However, the concept of the disclosure is not limited thereto. For example, when the radius of curvature r1 of the opening 105 at the upper surface 100a of the first plate 100 is sufficiently large, the corner of the opening 105 may not be vulnerable to fracture even when the radius of curvature r3 of the opening 105 at the lower surface 100b of the first plate 100 is less than one half of the radius of curvature r1 of the opening 105 at the upper surface 100a of the first plate 100.

Meanwhile, when considering a case in which the second inner wall surface 112 is not included in the inner wall surface 110 of the opening 105, the first inner wall surface 111 may extend from the first edge 1111 to a first virtual second edge 1112a.

The first inner wall surface 111 extended to the first virtual second edge 1112a may be referred to as a virtual first inner wall surface 111a. A second inner wall surface provided at a first virtual second edge 1112a may be referred to as a virtual second inner wall surface 112a. The virtual second inner wall surface 112a may extend from the first virtual second edge 1112a to a virtual third edge 1122a. The virtual second inner wall surface 112a may represent a chamfered portion formed for edge treatment as the first plate 100 is processed. That is, the second inner wall surface 112 according to an embodiment of the disclosure may be distinguished from the virtual second inner wall surface 112a representing a chamfered portion.

A height h2a of the virtual second inner wall surface 112a representing a chamfered portion may be very small or substantially negligible. Accordingly, in the first plate 100 including the virtual first inner wall surface 111a and the virtual second inner wall surface 112a, the structural stability at the end of the inner wall surface 110 may be reduced due to difficulty in ensuring structural thickness. In the first plate 100 including the virtual first inner wall surface 111a and the virtual second inner wall surface 112a, the inner wall surface 110 may be thinned, and fracture may occur when stress is applied.

A radius of curvature r2a of the curved portion 113 at the virtual second inner wall surface 112a representing a chamfered portion may be very small or substantially negligible. Accordingly, in the first plate 100 including the virtual first inner wall surface 111a and the virtual second inner wall surface 112a, the radius of curvature of the corner of the opening 105 at the lower surface 100b of the first plate 100 may be very small or substantially negligible. In the first plate 100 including the virtual first inner wall surface 111a and the virtual second inner wall surface 112a, the corners of the opening 105 at the lower surface 100b of the first plate 100 may be provided in a sharp shape. Accordingly, stress acting on the inner wall surface 110 may be concentrated at the corners of the opening 105. Accordingly, the inner wall surface 110 may be damaged at the corners of the opening 105.

Meanwhile, the description of the first plate 100 including the virtual first inner wall surface 111a and the second inner wall surface 112 may be equally applied to a case in which the virtual first inner wall surface 111b is extended to the end without the chamfered virtual second inner wall surface 112a. When the virtual first inner wall surface 111b is extended to the end, the virtual first inner wall surface 111b may extend to a second virtual second edge 1112b. Accordingly, the end of the inner wall surface 110, at which the second virtual second edge 1112b is located, may become vulnerable to damage as it becomes structurally thin. Accordingly, since the corners of the opening 105 at the lower surface 100b of the first plate 100 are provided to be sharply angled, stress may be concentrated and become vulnerable to damage.

In the drawing, the inclination angle of the first inner wall surface 111 is illustrated as 45 degrees, but the concept of the disclosure is not limited thereto. The inclination angle of the first inner wall surface 111 may be provided to have various angles in a range of 20 degrees to 70 degrees with respect to the lower surface 100b of the first plate 100.

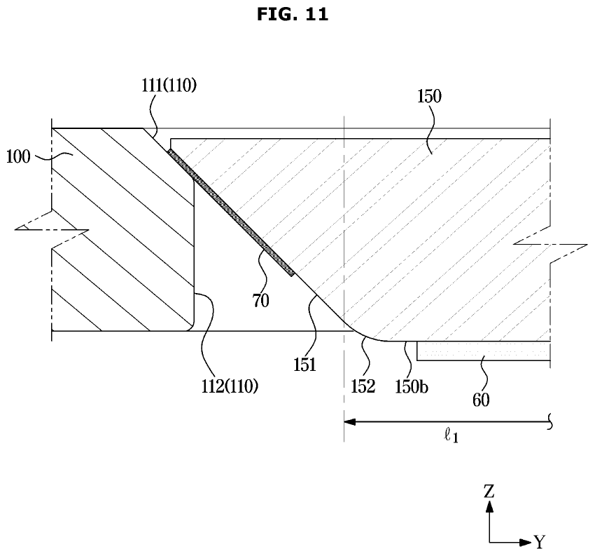

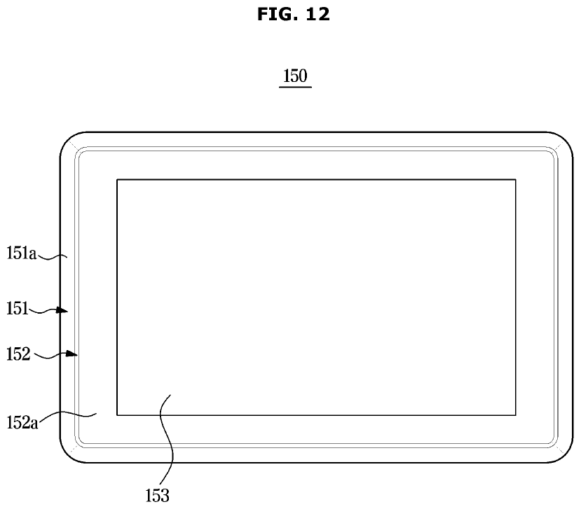

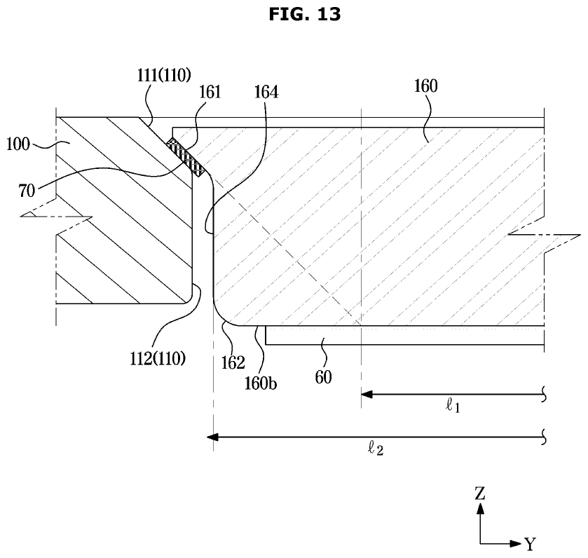

FIG. 11 illustrates a side cross-section of a part of a cooking apparatus according to an embodiment of the disclosure. FIG. 12 is a rear view of a second plate in a cooking apparatus according to an embodiment of the disclosure. FIG. 13 illustrates a side cross-section of a part of a cooking apparatus according to an embodiment of the disclosure.

In the following description, for convenience of description, components that are substantially the same as or similar to those described with reference to FIGS. 6 to 8 may be omitted or briefly described.

Referring to FIGS. 11 to 13, the second plate 150 may be fixed to the first plate 100 through an adhesive member 70. The adhesive member 70 may fix the inclined surface 151 of the second plate 150 and the first inner wall surface 111 of the first plate 100. The adhesive member 70 may be provided between the second plate 150 and the first plate 100.

The adhesive member 70 may include various adhesive materials capable of bonding the first plate 100 and the second plate 150. For example, the adhesive member 70 may include silicone.

Meanwhile, since the second plate 150 is formed of a substantially transparent material, the adhesive member 70 may be recognized by a user through a side surface of the second plate 150. The adhesive member 70 may be applied to the inclined surface 151 of the side surface of the second plate 150. The adhesive member 70 applied to the inclined surface 151 may have partially non-uniform portions. When the non-uniform portions of the adhesive member 70 are recognized by a user, the aesthetic appearance may be degraded.

Accordingly, the second plate 150 according to one embodiment may be provided such that the adhesive member 70 applied to the side surface is not visible to a user. The side surface of the second plate 150 may include a side printed surface 151a such that the side surface becomes substantially opaque. The inclined surface 151 of the second plate 150 may include the side printed surface 151a.

Accordingly, the adhesive member 70 applied to the side surface of the second plate 150 may be applied on the side printed surface 151a. The adhesive member 70 applied on the side printed surface 151a may not be recognized by a user.

The second plate 150 may include a rear printed surface 152a. The rear printed surface 152a may be printed along an edge of the lower surface 150b of the second plate 150. As the rear printed surface 152a is printed, the edge of the lower surface 150b of the second plate 150 may become substantially opaque. The edge of the lower surface 150b of the second plate 150 may be provided to be relatively more opaque than a display area 153 provided at the central portion of the lower surface 150b of the second plate 150.

Specifically, in the cooking apparatus 1 according to an embodiment of the disclosure, the second plate 150 may be provided to be spaced a predetermined distance from the display 20. Accordingly, a user may recognize not only the display 20 but also a peripheral portion of the display 20 through the second plate 150. When the peripheral portion of the display 20 is recognized by a user, the aesthetic sense may be reduced. By including the rear printed surface 152a on the lower surface 150b, the second plate 150 may prevent the peripheral portion of the display 20 from being recognized by a user. Accordingly, the user's concentration on display may be increased.

The second plate 150 may include a rounded portion 152 to improve printing quality. The rounded portion 152 may be provided at the edge of the lower surface 150b of the second plate 150. The rounded portion 152 may be provided to smoothly connect between the lower surface 150b and the side surface of the second plate 150. For example, a radius of curvature of the rounded portion 152 may be provided to be 0.5 mm or more and 2.0 mm or less. However, the concept of the disclosure is not limited thereto. For example, the radius of curvature of the rounded portion 152 may be about 0.2 mm to an extent sufficient to remove angled portions at the edges of the second plate 150. In addition, for example, the second plate 150 may not include the rounded portion 152.

As the rounded portion 152 is provided on the lower surface 150b of the second plate 150, angled edges between the side surface and the lower surface in the second plate 150 may be removed. Accordingly, the printing quality of the second plate 150 may be improved.

The second plate 150 may have an interface region l1. The interface region l1 may refer to a region capable of providing visual information of the display 20 to a user. The area of the interface region l1 may correspond to the area of the lower surface 150b of the second plate 150. A detailed description of this will be described below.

Referring to FIG. 13, the cooking apparatus 1 according to an embodiment of the disclosure may be provided such that, when a display 20 having the same size is applied, the opening 105 of the first plate 100 has a smaller size. That is, the cooking apparatus 1 according to an embodiment may be provided to minimize visibility of the interior of the main body 10 to a user by reducing a gap formed between the circumference of the opening 105 of the first plate 100 and the outer periphery of the display 20. Accordingly, the aesthetics of the cooking apparatus 1 according to an embodiment may be increased.

A screen of the display 20 may be displayed through the second plate 160. That is, visual information of the display 20 may pass through the second plate 160 and be recognized by a user. In this case, an interface region l2 may be formed in the second plate 160, the interface region l2 being a region through which visual information in the form of light generated from the display 20 may pass without refraction and be transmitted to a user. In the second plate 160 provided such that the size of the upper surface is larger than the size of the lower surface 160b, the interface region l2 may be a region corresponding to the lower surface 160b of the second plate 160.

In order for visual information of the display 20 to pass through the second plate 160 without refraction, the screen of the display 20 may be provided to be positioned inside the interface region l2. The size of the area of the lower surface 160b of the second plate 160 may be provided to be larger than or at least equal to the area of the screen of the display 20. That is, the minimum size of the lower surface 160b of the second plate 160 may correspond to the size of the screen of the display 20.

Accordingly, visual information generated from the display 20 may pass through the second plate 160 in a direction perpendicular to the lower surface 160b of the second plate 160 over the entire screen area of the display 20. Accordingly, visual information may be prevented from being refracted when passing through the second plate 160.

Accordingly, when visual information of the display 20 is transmitted to a user through the second plate 160, visual information at the edge of the screen of the display 20 may be prevented from being refracted while passing through an inclined surface 161 of the second plate 160.

Referring to FIG. 13, the second plate according to an embodiment of the disclosure may be provided such that the size of the interface region l2 on which the screen is displayed increase within predetermined specifications of the opening 105 or the first plate 100. For this purpose, the side surface of the second plate 160 may include an inclined surface 161 and an extension surface 164. The extension surface 164 may be provided to be bent from one side of the inclined surface 161 and extend in a vertical direction.

The interface region l2 of the second plate 160 when the extension surface 164 is formed on one side of the inclined surface 161 may be larger than a virtual interface region l1 when the side surface of the second plate 160 includes only the inclined surface 161 without including the extension surface 164. In other words, by including the extension surface 164, the interface region l2 of the second plate may be increased. By including the extension surface 164, the second plate 160 may increase the size of the screen of the display 20 within the same predetermined specifications of the opening 105 or the first plate 100.

In other words, when the second plate 160 includes the extension surface 164, the size of the opening 105 of the first plate 100 may be reduced under a condition that the size of the screen of the display 20 is the same. That is, when the cooking apparatus 1 according to an embodiment displays a screen of the same size, the size of the opening 105 may be reduced when the second plate 160 includes the extension surface 164, as compared with when the second plate 160 does not include the extension surface 164. As the size of the opening 105 in the first plate decreases, aesthetics may be increased.

Meanwhile, the extension surface 164 of the second plate 160 may guide coupling of the second plate 160 to the first plate 100 during a manufacturing process. Specifically, the second plate 160 may be inserted to be seated in the opening 105 of the first plate 100. In this case, even when the center of the second plate 160 is slightly misaligned from the center of the opening 105, the extension surface 164 of the second plate 160 and the second inner wall surface 112 of the first plate may guide the insertion of the second plate 160.

The extension surface 164 and the inclined surface 161 may be provided to be smoothly connected. The side surface of the second plate 160 may be bent to include a radius of curvature between the extension surface 164 and the inclined surface 161. A rounded portion 162 may be provided at the edge of the lower surface 160b of the second plate 160.

Meanwhile, referring to FIG. 11, the side surface of the second plate 150 according to an embodiment of the disclosure may be provided to include only the inclined surface 151. Accordingly, the processing quality of the side surface of the second plate 150 may be enhanced.

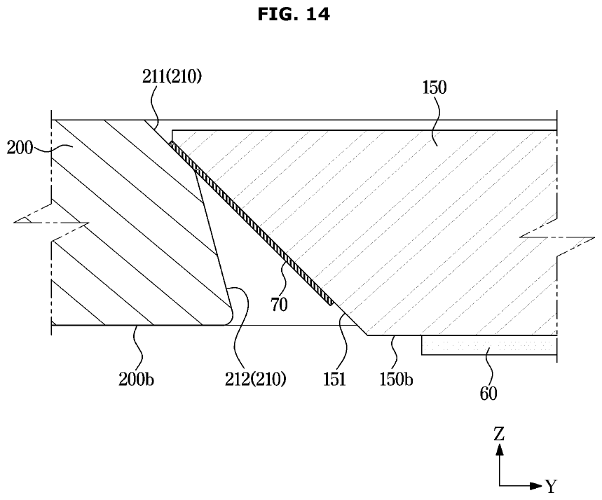

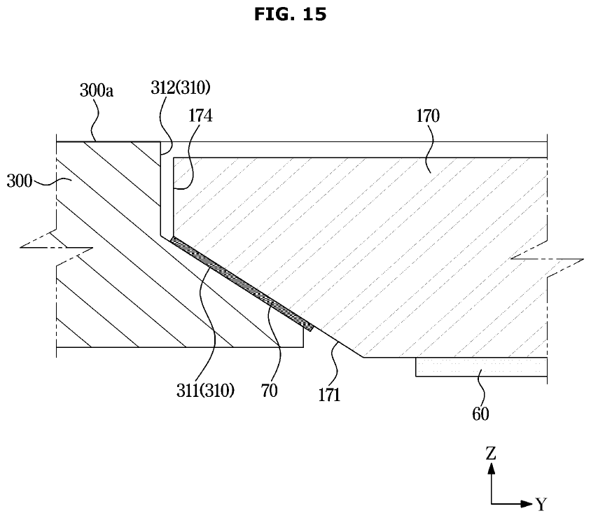

FIG. 14 illustrates a side cross-section of a part of a cooking apparatus according to an embodiment of the disclosure. FIG. 15 illustrates a side cross-section of a part of a cooking apparatus according to an embodiment of the disclosure.

In the following description, for convenience of description, components that are substantially the same as or similar to those described with reference to FIGS. 9 and 10 may be omitted or briefly described.

In addition, in the following description, for convenience of description, components of the second plate that are substantially the same as or similar to those described with reference to FIGS. 6 to 8 may be omitted or briefly described.

Referring to FIGS. 14 and 15, a second inner wall surface 212 of the first plate 200 may be provided to be inclined at a predetermined angle. For example, the second inner wall surface 212 may be provided to be inclined downward toward the center of the opening 105. In this case, with respect to a direction toward the center of the opening 105, the second inner wall surface 212 may be provided to be inclined downward more steeply than the first inner wall surface 211. The second inner wall surface 212 may be bent and extend from the first inner wall surface 211 in a direction along the thickness direction of the first plate 200.

Accordingly, even when the second inner wall surface 212 is inclined, the inner wall surface 210 of the first plate 200 may ensure a structural thickness at an end thereof.

The content described with reference to FIGS. 9 and 10 may be applied equally. When the inclination of the second inner wall surface 212 is steeper than the inclination of the first inner wall surface 211, the second inner wall surface 212 may be provided to limit the extension of the first inner wall surface 211. Accordingly, the end of the inner wall surface 210 may be prevented from thinning.

In addition, the degree of decrease in the radius of curvature of the curved portions 113 provided on the second inner wall surface 212 may be smaller than the degree of decrease in the radius of curvature of the curved portions 113 provided on the first inner wall surface 211. Accordingly, a reduction in a radius of curvature of the opening 105 at the lower surface 200b of the first plate 200 may be limited to some extent.

The second inner wall surface 112, 212, or 312 may be provided on one side of the first inner wall surface 111, 211 or 311. The second inner wall surface 112, 212, or 312 may be provided at one end on the upper or lower side of the first inner wall surface 111, 211, or 311.

For example, referring to FIGS. 9 and 14, the second inner wall surface 112 or 212 may be provided between the first inner wall surface 111 or 211 and the lower surface 100b or 200b of the first plate 100; 200. Accordingly, the second inner wall surface 112 or 212 may be provided at the end of the inner wall surface 110 or 210. The second inner wall surface 112 or 212 may be provided at one end of the first inner wall surface 111 or 211 on a side facing the center of the opening 105.

For example, referring to FIG. 15, the second inner wall surface 312 may be provided between an upper surface 300a of a first plate 300 and a first inner wall surface 311. Accordingly, the second inner wall surface 312 may be provided to extend downward from the boundary of the opening 105 at the upper surface 300a of the first plate 300. Even in this case, the second inner wall surface 312 may be provided to limit extension of the first inner wall surface 311 in the direction of the center of the opening 105. In other words, an inner wall surface 310 may limit a reduction in a radius of curvature in a downward direction at a corner of the opening 105 by the second inner wall surface 312. The second inner wall surface 312 may prevent the corner of the opening 105 from becoming vulnerable to damage.

Corresponding to the inner wall surface 310 of the first plate 300, the side surface of the second plate 170 may include an extension surface 174 and an inclined surface 171. The extension surface 174 may be positioned on the upper side of the inclined surface 171.

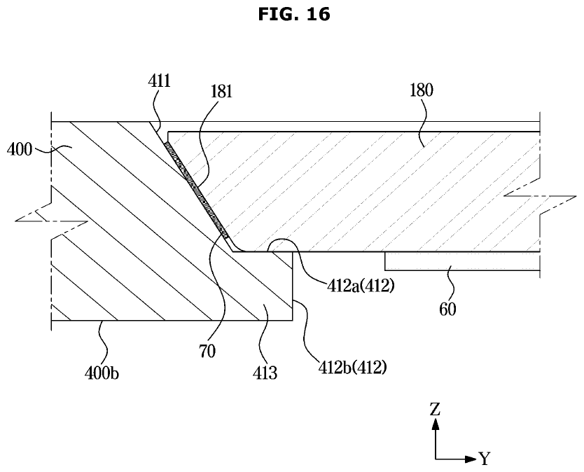

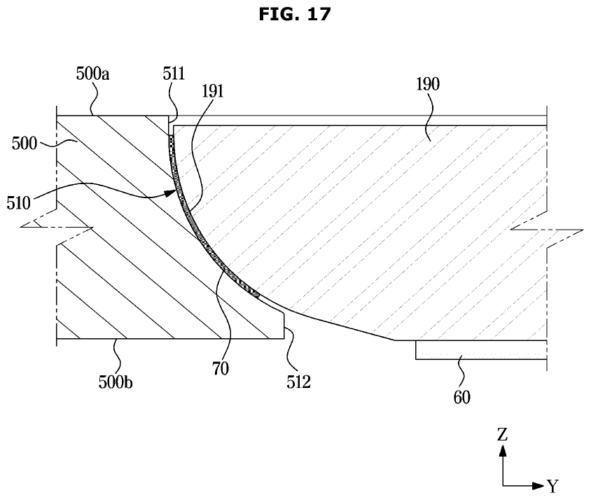

FIG. 16 illustrates a side cross-section of a part of a cooking apparatus according to an embodiment of the disclosure. FIG. 17 illustrates a side cross-section of a part of a cooking apparatus according to an embodiment of the disclosure.

In addition, in the following description, for convenience of description, components of the second plate that are substantially the same as or similar to those described with reference to FIGS. 6 to 8 may be omitted or briefly described.

Referring to FIG. 16, a first plate 400 may include a first inner wall surface 411 and a second wall portion 413 protruding from an inner wall surface 410. A second inner wall surface 412 may be provided on a surface of the second wall portion 413. The second inner wall surface 412 of the first plate 200 may include a horizontal second inner wall surface 412a and a vertical second inner wall surface 412b.

A second plate 180 includes an inclined surface 181. The second wall portion 413 may support the second plate 180 upward. The horizontal second inner wall surface 412a may be in contact with and support the second plate 180. The second plate 180 may be seated on the horizontal second inner wall surface 412a. The second wall portion 413 may be provided to ensure a structural thickness at the end of the inner wall surface 410 of the first plate 400. The vertical second inner wall surface 412b may be provided to limit a reduction in a radius of curvature of the opening 105 at a lower surface 400b of the first plate 400.

Referring to FIG. 17, a first inner wall surface 511 of an inner wall surface 510 of a first plate 500 may be provided to have a curvature. In the drawing, the inclination of the first inner wall surface 511 is illustrated as being gradually bent from an upper surface 500a of the first plate 500 to become gentler with respect to the lower surface 500b of the first plate 500 as the first inner wall surface 511 extends toward the center of the opening 105, but the concept of the disclosure is not limited thereto. The inclination of the first inner wall surface 511 may be gradually bent to become gentler or steeper toward the center of the opening 105.

The first plate 500 may include a second inner wall surface 512. The second inner wall surface 512 may be provided to ensure a structural thickness at the end of the inner wall surface 510 of the first plate 500. The second inner wall surface 512 may be provided to limit a reduction in a radius of curvature of the opening 105 at the lower surface 500b of the first plate 500.

A second plate 190 may be seated on the inner wall surface 510. An inclined surface of the second plate 190 may be provided to have a curvature. In the drawing, the curved surface 191 of the second plate 190 is illustrated as being gradually bent to be curved to become gentler toward the center of the second plate 190, but the concept of the disclosure is not limited thereto. The inclined surface of the second plate 190 may be gradually bent to be curved to become gentler or steeper toward the center of the second plate 190.

The curvature of the inner wall surface 510 and the curvature of the inclined surface may be the same. Accordingly, a load of the second plate 190 may be distributed to the inner wall surface 510 of the first plate 500.

A cooking apparatus 1 according to a concept of the disclosure includes: a first plate 100 provided with one or more cooking zones 101 and an opening 105, a second plate 150 seated in the opening 105, and a display 20 on which visual information is displayed through the second plate 150, wherein an inner wall surface 110 of the opening 105 includes a first inner wall surface 111 inclined to support the second plate 150, and a second inner wall surface 112 bent and extending from the first inner wall surface 111.

A side surface of the second plate 150 may include an inclined surface 151 provided parallel to the first inner wall surface 111, and the inclined surface 151 is supported by the first inner wall surface 111.

The side surface of the second plate 160 may further include an extension surface 164 extending from the inclined surface 161 in a vertical direction.

The second inner wall surface 112 may be provided between an upper surface 100a of the first plate 100 and the first inner wall surface 111 or between a lower surface 100b of the first plate 100 and the first inner wall surface 111.

The inner wall surface 110 may include one or more straight portions 114 arranged along a circumference of the opening 105 in a horizontal direction and one or more curved portions 113 extending from the straight portions 114 in a horizontal direction, and the curved portions 113 may extend from an upper surface 100a to a lower surface 100b of the first plate 100.

The curved portions 113 may have a radius of curvature that decreases in a downward direction in a section in which the first inner wall surface 111 is formed, and have a radius of curvature maintained in a downward direction in a section in which the second inner wall surface 112 is formed.

The first inner wall surface 111 may extend from a circumference of the opening 105 toward a center of the opening 105.

The second inner wall surface 112 may be provided at one end of the first inner wall surface 111 such that an extension range of the first inner wall surface 111 is limited.

The second inner wall surface 112 may be provided to extend in a substantially vertical direction.

With respect to a thickness direction of the first plate 100, a height h2 of the second inner wall surface 112 may be provided to be greater than or equal to a height h3 of the first inner wall surface 111.

An upper surface 150a of the second plate 150 may be provided to be positioned below an upper surface 100a of the first plate 100.

The display 20 may be positioned on a lower surface 150b of the second plate 150, and a touch film 60 is attached between the second plate 150 and the display 20.

The second plate 150 may be formed of a material that may be relatively more transparent than the first plate 100.

An adhesive member 70 may be provided between the first inner wall surface 111 of the first plate 100 and the side surface of the second plate 150, and a side printed surface 151a opaquely printed may be provided on the side surface of the second plate 150.

A rear printed surface 152a opaquely printed may be provided at an edge of the lower surface 150b of the second plate 150.

A cooking apparatus 1 according to an embodiment of the present disclosure includes a display 20 on which visual information is displayed; a first plate 100 provided with one or more cooking zones 101 and an opening 105 having a shape including a corner at a position corresponding to the display 20, the opening 105 having an inclined structure on an inner wall surface 110 thereof; a second plate 150 inserted into the opening 105 of the first plate 100 and seated on the inner wall surface 110, wherein the opening 105 includes a curved portion 113 extending from an upper surface 100a to a lower surface 100b of the first plate 100 such that the corner is rounded, and the curved portion 113 is formed such that a radius of curvature at the lower surface 100b of the first plate 100 is smaller than a radius of curvature at the upper surface 100a of the first plate 100.

The inner wall surface 110 may include a first inner wall surface 111 inclined downward toward a center of the opening 105 to support the second plate 150, and a second inner wall surface 112 bent and extending from the first inner wall surface 111.

The curved portion 113 may have a radius of curvature that decreases in a downward direction in a section in which the first inner wall surface 111 is formed, and a radius of curvature maintained in the downward direction in a section in which the second inner wall surface 112 is formed.

The second inner wall surface 112 may be provided to be more steeply inclined downward than the first inner wall surface 111.

The second plate 150 may include a material that is relatively more transparent than the first plate 100, and a side surface of the second plate 150 may include an inclined surface 151 provided parallel to the first inner wall surface 111.

According to the concept of the present disclosure, the cooking apparatus can reduce production costs by applying a separate second plate only to a display portion.

According to the concept of the present disclosure, the cooking apparatus forms a display portion with a simple configuration. Accordingly, the number of components required to form the display portion can be reduced, thereby improving cost efficiency and productivity, and enhancing aesthetic appearance.

The effects of the present disclosure are not limited to those described above, and other effects that are not described above will be clearly understood by those skilled in the art from the above detailed description.

Although the present disclosure has been described in detail above with reference to exemplary embodiments, those of ordinary skill in the technical field to which the present invention pertains should be able to understand that various modifications and alterations may be made without departing from the technical spirit and scope of the present invention.

What is claimed is:

1. A cooking apparatus comprising:
a first plate having one or more cooking zones, the first plate having an opening formed therein;
a second plate inserted into the opening and seated on the first plate;
a display disposed in a position corresponding to a position of the opening so that visual information is displayed on the display and visible through the second plate;
wherein the first plate further comprises an inner wall surface which is a boundary surrounding inside of the opening thereby forming the opening, the inner wall surface includes:
a first inner wall surface formed along the boundary of the opening, and inclined to support the second plate in response to the second plate being seated on the first plate; and
a second inner wall surface bent and extending from the first inner wall surface.

2. The cooking apparatus of claim 1, wherein the second plate includes a side surface which includes an inclined surface parallel to the first inner wall surface, and the inclined surface is supported by the first inner wall surface in response to the second plate being seated on the first plate.

3. The cooking apparatus of claim 2, wherein the side surface of the second plate further includes an extension surface extending from the inclined surface in a vertical direction.

4. The cooking apparatus of claim 1, wherein the second inner wall surface is disposed between a lower surface of the first plate and the first inner wall surface.

5. The cooking apparatus of claim 1, wherein the second inner wall surface is disposed between an upper surface of the first plate and the first inner wall surface.

6. The cooking apparatus of claim 1, wherein the inner wall surface includes:
one or more straight portions arranged along the boundary of the opening in a horizontal direction; and
one or more curved portions extending from the one or more the straight portions in the horizontal direction, and
wherein one or more curved portions extend from an upper surface of the first plate to a lower surface of the first plate.

7. The cooking apparatus of claim 6, wherein the one or more curved portions have:
a radius of curvature that decreases in a downward direction in a section in which the first inner wall surface is formed; and
a radius of curvature maintained in a downward direction in a section in which the second inner wall surface is formed.

8. The cooking apparatus of claim 1, wherein the first inner wall surface extends from the boundary of the opening toward a center of the opening.

9. The cooking apparatus of claim 8, wherein the second inner wall surface is disposed at one end of the first inner wall surface to limit an extension range of the first inner wall surface.

10. The cooking apparatus of claim 1, wherein the second inner wall surface extends in a substantially vertical direction.

11. The cooking apparatus of claim 1, wherein, with respect to a thickness direction of the first plate, a height of the second inner wall surface is greater than or equal to a height of the first inner wall surface.

12. The cooking apparatus of claim 11, wherein the height of the second inner wall surface is greater than or equal to one half of a thickness of the inner wall surface.

13. The cooking apparatus of claim 1, wherein an upper surface of the second plate is positioned below an upper surface of the first plate in response to the second plate being seated on the first plate.

14. The cooking apparatus of claim 13, wherein a lower surface of the second plate is positioned below a lower surface of the first plate in response to the second plate being seated on the first plate.

15. The cooking apparatus of claim 14, wherein the lower surface of the second plate is protruded downward from the lower surface of the first plate in response to the second plate being seated on the first plate.

16. The cooking apparatus of claim 1, wherein the display is positioned on a lower surface of the second plate, and the cooking apparatus further comprises a touch film which is attached between the second plate and the display.

17. The cooking apparatus of claim 1, wherein the second plate is formed of a material that is relatively more transparent than a material of the first plate.

18. The cooking apparatus of claim 17, further comprising an adhesive member disposed between the first inner wall surface of the first plate and a side surface of the second plate, and the second plate further comprises a side printed surface that is opaquely printed and disposed on the side surface of the second plate.

19. The cooking apparatus of claim 17, wherein the second plate further includes a rear printed surface that is opaquely printed and disposed at an edge of a lower surface of the second plate.
